(19) United States
(12) Patent Application Publication
(10) Pub. No.: US 2026/0160961 A1
(43) Pub. Date: Jun. 11, 2026

(54) TRANSMITTING-END FIBER ALIGNMENT DEVICE, AN OPTICAL CONNECTOR, AND A METHOD FOR TRANSMITTING-END FIBER ALIGNMENT

(71) Applicant: PhotonIX Labs, LLC, Foster City, CA (US)

(72) Inventor: Patrick Chiang, Foster City, CA (US)

(21) Appl. No.: 19/387,764

(22) Filed: Nov. 13, 2025

Related U.S. Application Data
(60) Provisional application No. 63/720,295, filed on Nov. 14, 2024.

(51) Int. Cl. G02B 6/42; H01S 5/42

(52) U.S. Cl. CPC G02B 6/4222; G02B 6/4203; G02B 6/4249; H01S 5/423

(57) ABSTRACT

A transmitting-end fiber alignment device, includes at least one additional laser source that is provided in addition to a light source array including a plurality of light sources, and at least one quadrant detector that corresponds to the at least one additional laser source. The at least one additional laser source is positioned according to a given geometric relationship with respect to a first geometric shape that covers all of the plurality of light sources at a top surface of the light source array. A respective quadrant detector that is each of the at least one quadrant detector, is configured for sensing at least a portion of a reflected light beam that is originally transmitted by a respective additional laser source that corresponds to the respective quadrant detector, such that a misalignment of the light source array is detected.

### CROSS-REFERENCE TO RELATED APPLICATIONS

The present application claims priority to U.S. provisional patent application App. No. 63/720295, filed on Nov. 14, 2024, the contents of which are incorporated by reference in their entirety.

### FIELD OF THE INVENTION

The present disclosure relates to the field of fiber alignment. More specifically, the present disclosure relates to techniques for a transmitting-end fiber alignment device, an optical connector, and a method for transmitting-end fiber alignment.

### BACKGROUND OF THE INVENTION

With the development of data center networks, cloud computing, and large-scale artificial intelligence models, optical links are widely adopted for establishing network links with a longer reach than copper links. However, optical links are faced with challenges of alignment accuracy and link reliability. Misalignment may make it difficult to capture most of the light to be coupled into a fiber, and the coupling efficiency may be compromised. During usage of optical links, channels may be determined to have failed, for a variety of possible reasons like device malfunction, corrosion, or processing conditions. Since optical modules are highly integrated and difficult to detach once installed, the operation of data center networks that rely on optical modules for data transmission, data processing, and data storage may be affected by unreliable optical links.

Some prior art references provide measures for fiber alignment. U.S. Pat. No. 6,188,472B1 discloses that, an optical switch receives light through an optical pathway and routes the light to fibers in a fiber bundle, so that light reflected back to the optical switch from magneto-optical storage media along one of the fibers in the fiber bundle may be routed to the optical pathway. U.S. Pat. No. 6,950,570B1 discloses that light beams travel from incoming fibers to outgoing fibers, and mirrors are positioned to direct light beams to appropriate fibers. The prior art references rely on incoming light beams on the receiving end and complicated optical systems for aligning the light beams over cores of the fibers, and have complicated optical components for routing light beams to appropriate fibers. As the data scale of data transmission in data center networks rapidly increases, the number of fibers, or the number of cores of a multi-core fiber, also rapidly increases to reach hundreds, or even thousands. And with a huge number of fibers in one fiber bundle or a huge number of cores in a multi-core fiber, the complexity and scale of optical systems for routing light beams and aligning fibers are greatly increased, and this also increases the costs and size of optical connectors.

In light of the above considerations, the present disclosure provides a transmitting-end fiber alignment device, an optical connector, and a method for transmitting-end fiber alignment, which not only provide reliable optical links but also improve alignment accuracy with simplified system design and lower costs.

### SUMMARY OF THE INVENTION

In accordance with a first aspect, the present disclosure provides a transmitting-end fiber alignment device, including: at least one additional laser source that is provided in addition to a light source array including a plurality of light sources, the at least one additional laser source is positioned according to a given geometric relationship with respect to a first geometric shape that covers all of the plurality of light sources at a top surface of the light source array; and at least one quadrant detector that corresponds to the at least one additional laser source. A respective quadrant detector that is each of the at least one quadrant detector, is configured for sensing at least a portion of a reflected light beam that is originally transmitted by a respective additional laser source that corresponds to the respective quadrant detector, such that a misalignment of the light source array is detected.

With reference to the first aspect, the transmitting-end fiber alignment device, provides an architecture that includes the at least one additional laser source and the at least one quadrant detector, achieves centering and misalignment detection of each additional laser source based on the sensing of reflected light beam by corresponding quadrant detector; provides reliable optical links and improves alignment accuracy with simplified system design and lower costs; not only considers all possible variances of the requirements of the transmitting end, but also considers the complexity and costs associated with optical connectors in implementations of large data scale; uses the particular layout of the at least one additional laser source to simplify the calculation of the measured light spot as against the correct position, and provide region-sensitive misalignment detection, such that different parts of the light source array may be treated respectively.

In accordance with the first aspect of the present disclosure, in a manner of implementation, the plurality of light sources are configured for transmitting output light through a fiber array including a plurality of outgoing fibers.

In accordance with the first aspect of the present disclosure, in a manner of implementation, the plurality of outgoing fibers are silicon waveguide fibers, a multicore imaging fiber, or, active optical cables.

In accordance with the first aspect of the present disclosure, in a manner of implementation, the plurality of outgoing fibers are mapped to the plurality of light sources in a one-to-one correspondence.

In accordance with the first aspect of the present disclosure, in a manner of implementation, the plurality of outgoing fibers are mapped to the plurality of light sources in a multiple-to-one correspondence.

In accordance with the first aspect of the present disclosure, in a manner of implementation, at least one reflective element is provided in addition to the fiber array and positioned according to the given geometric relationship with respect to a second geometric shape that covers all of the plurality of outgoing fibers at an end surface of the fiber array, the at least one reflective element is mapped to the at least one additional laser source in a one-to-one correspondence, and, the respective quadrant detector is configured for sensing at least a portion of the reflected light beam that is originally transmitted by the respective additional laser source that corresponds to the respective quadrant detector and reflected by a respective reflective element out of the at least one reflective element that corresponds to the respective additional laser source.

In accordance with the first aspect of the present disclosure, in a manner of implementation, a size of the first geometric shape that covers all of the plurality of light sources at the top surface of the light source array is substantially the same as a size of the second geometric shape that covers all of the plurality of outgoing fibers at the end surface of the fiber array.

In accordance with the first aspect of the present disclosure, in a manner of implementation, the at least one reflective element is an optical mirror made of free-space MEMS.

In accordance with the first aspect of the present disclosure, in a manner of implementation, the at least one reflective element is a silicon waveguide fiber, or, an optical fiber.

In accordance with the first aspect of the present disclosure, in a manner of implementation, the respective additional laser source and the respective reflective element that corresponds to the respective additional laser source are configured for measuring a reference coupling efficiency related to a surrounding region of the respective additional laser source, and, the reference coupling efficiency is used for determining a regional coupling efficiency of one or more light sources out of the plurality of light sources within the surrounding region of the respective additional laser source.

In accordance with the first aspect of the present disclosure, in a manner of implementation, the regional coupling efficiency is used for a decision of shutting down the one or more light sources out of the plurality of light sources within the surrounding region of the respective additional laser source, and, the measuring the reference coupling efficiency is performed independent of data transmission by the light source array in different time divisions.

In accordance with the first aspect of the present disclosure, in a manner of implementation, a total number of the at least one additional laser source is one, and, the given geometric relationship with respect to the first geometric shape indicates that the at least one additional laser source is positioned at a geometric center of the first geometric shape.

In accordance with the first aspect of the present disclosure, in a manner of implementation, a total number of the at least one additional laser source is three, and, the given geometric relationship with respect to the first geometric shape indicates that the at least one additional laser source are positioned at three vertices of a triangle respectively, or, the total number of the at least one additional laser source is four, and, the given geometric relationship with respect to the first geometric shape indicates that the at least one additional laser source are positioned at four vertices of a cross respectively, or, the total number of the at least one additional laser source is five, and, the given geometric relationship with respect to the first geometric shape indicates that the at least one additional laser source are positioned at five vertices of a pentagon respectively, or, the total number of the at least one additional laser source is six, and, the given geometric relationship with respect to the first geometric shape indicates that the at least one additional laser source are positioned at six vertices of a hexagon respectively.

In accordance with the first aspect of the present disclosure, in a manner of implementation, a total number of the at least one additional laser source is at least three, and, the given geometric relationship with respect to the first geometric shape indicates that the at least one additional laser source are positioned along a circumference of the first geometric shape that is determined based on a set-covering algorithm for covering a set of points corresponding to the plurality of light sources.

In accordance with the first aspect of the present disclosure, in a manner of implementation, a total number of the at least one additional laser source is at least three, and, the given geometric relationship with respect to the first geometric shape indicates that the at least one additional laser source are positioned on a boundary of the first geometric shape that is a minimum enclosing circle, the plurality of light sources are inside the minimum enclosing circle.

In accordance with the first aspect of the present disclosure, in a manner of implementation, the given geometric relationship with respect to the first geometric shape further indicates that, the at least one additional laser source are evenly distributed along a circumference of the minimum enclosing circle, or, the at least one additional laser source are distributed in a centrally symmetric manner around a center of the minimum enclosing circle.

In accordance with the first aspect of the present disclosure, in a manner of implementation, the given geometric relationship with respect to the first geometric shape further indicates that the at least one additional laser source are distributed at every preset angle along a center of the minimum enclosing circle, and, the preset angle is 30 degrees, 45 degrees, 60 degrees, 72 degrees, 90 degrees, or 120 degrees.

In accordance with the first aspect of the present disclosure, in a manner of implementation, the at least one additional laser source is one or more VCSELs, and, the plurality of light sources are VCSELs or Micro-LEDs.

In accordance with a second aspect, the present disclosure provides an optical connector, including: a light source array including a plurality of light sources; a fiber array including a plurality of outgoing fibers, the plurality of light sources are configured for transmitting output light through the plurality of outgoing fibers; at least one additional laser source that is provided in addition to the light source array including the plurality of light sources, the at least one additional laser source is positioned according to a given geometric relationship with respect to a first geometric shape that covers all of the plurality of light sources at a top surface of the light source array; and at least one quadrant detector that corresponds to the at least one additional laser source. A respective quadrant detector that is each of the at least one quadrant detector, is configured for sensing at least a portion of a reflected light beam that is originally transmitted by a respective additional laser source that corresponds to the respective quadrant detector, such that a misalignment of the light source array is detected.

With reference to the second aspect, the optical connector, provides an architecture that includes the at least one additional laser source and the at least one quadrant detector, achieves centering and misalignment detection of each additional laser source based on the sensing of reflected light beam by corresponding quadrant detector; provides reliable optical links and improves alignment accuracy with simplified system design and lower costs; not only considers all possible variances of the requirements of the transmitting end, but also considers the complexity and costs associated with optical connectors in implementations of large data scale; uses the particular layout of the at least one additional laser source to simplify the calculation of the measured light spot as against the correct position, and provide region-sensitive misalignment detection, such that different parts of the light source array may be treated respectively.

In accordance with a third aspect, the present disclosure provides a method for transmitting-end fiber alignment, including: turning off a light source array including a plurality of light sources, and, turning on at least one additional laser source that is provided in addition to the light source array including the plurality of light sources, the at least one additional laser source is positioned according to a given geometric relationship with respect to a first geometric shape that covers all of the plurality of light sources at a top surface of the light source array; and using at least one quadrant detector that corresponds to the at least one additional laser source for detecting a misalignment of the light source array. A respective quadrant detector that is each of the at least one quadrant detector, is configured for sensing at least a portion of a reflected light beam that is originally transmitted by a respective additional laser source that corresponds to the respective quadrant detector.

With reference to the third aspect, the method for transmitting-end fiber alignment, provides an architecture that includes the at least one additional laser source and the at least one quadrant detector, achieves centering and misalignment detection of each additional laser source based on the sensing of reflected light beam by corresponding quadrant detector; provides reliable optical links and improves alignment accuracy with simplified system design and lower costs; not only considers all possible variances of the requirements of the transmitting end, but also considers the complexity and costs associated with optical connectors in implementations of large data scale; uses the particular layout of the at least one additional laser source to simplify the calculation of the measured light spot as against the correct position, and provide region-sensitive misalignment detection, such that different parts of the light source array may be treated respectively.

### BRIEF DESCRIPTION OF THE DRAWINGS

The drawings are provided to illustrate example embodiments described herein and are not intended to limit the scope of the present disclosure.

FIG. 1 is a schematic diagram illustrating a fiber bundle optical alignment between a fiber array and a light source array.

FIG. 2 is a schematic diagram illustrating a fiber bundle optical alignment using multiple VCSELs on a chip according to some embodiments.

FIG. 3 is a transmitting-end fiber alignment device according to some embodiments.

FIG. 4 is a schematic diagram illustrating a first setting of additional laser sources according to some embodiments.

FIG. 5 is a schematic diagram illustrating a second setting of additional laser sources according to some embodiments.

FIG. 6 is a schematic diagram illustrating a third setting of additional laser sources according to some embodiments.

FIG. 7 is a schematic diagram illustrating a fourth setting of additional laser sources according to some embodiments.

FIG. 8 is a schematic diagram illustrating a fifth setting of additional laser sources according to some embodiments.

FIG. 9 is a schematic diagram illustrating the distribution of additional laser sources along the circumference of the minimum enclosing circle according to some embodiments.

FIG. 10 is a schematic diagram illustrating several additional laser sources used for determining regional coupling efficiencies according to some embodiments.

FIG. 11 is a schematic diagram illustrating an optical connector according to some embodiments.

FIG. 12 is a flow chart illustrating a method for transmitting-end fiber alignment according to some embodiments.

### DETAILED DESCRIPTION

Aspects and embodiments of the present invention will now be discussed with reference to the accompanying figures. Further aspects and embodiments will be apparent to those skilled in the art. All documents mentioned in this text are incorporated herein by reference.

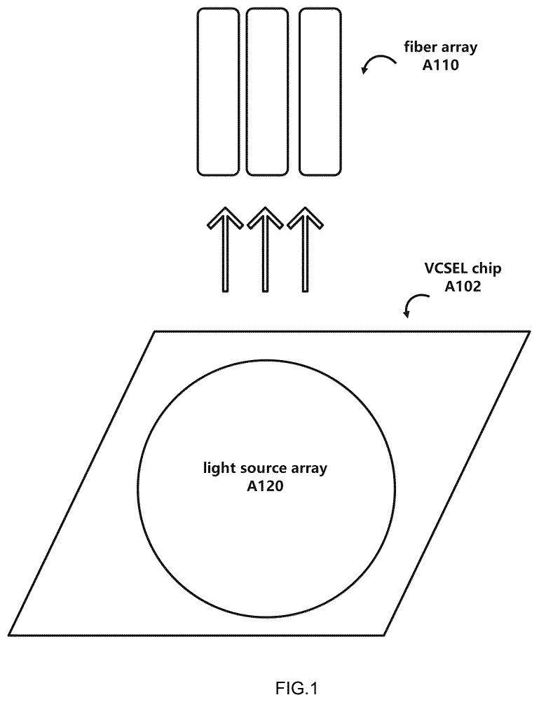

Referring to FIG. 1, FIG. 1 is a schematic diagram illustrating a fiber bundle optical alignment between a fiber array and a light source array. As shown in FIG. 1, a Vertical-Cavity Surface-Emitting Laser (VCSEL) chip, that is, a VCSEL chip A102 has a light source array A120 on top. The light source array A120 transmits light beams towards a fiber array A110. The fiber array A110 forms a fiber bundle, and one end of the fiber bundle is designed to be aligned with the VCSEL chip A102, such that the light source array A120 has much of the light beams coupled to the fiber array A110. The light source array A110 has multiple channels for transmitting light, and is a part of the transmitting end (TX) of an optical link. In some embodiments, the light source array A120 of the VCSEL chip A102 has a number of VCSELs that are used as the light sources. In some embodiments, the light source array A120 of the VCSEL chip A102 may have other types of light sources, such as Edge-Emitting Laser (EEL) or light-emitting diode (LED). Multiple channels of the light source array A120, such as by VCSELs, EELs, or LEDs, transmit light to be coupled into fibers, or fiber cores of a multi-core fiber. A correct fiber bundle optical alignment indicates that fibers or cores of a multi-core fiber are aligned correctly on top with respect to the deployment of the light source array A120. Misalignment of the optical link, for example, if a channel is misaligned with respect to the core of the appropriate fiber, makes it difficult to capture most of the light to be coupled into the appropriate fiber, thereby reducing the coupling efficiency and the quality of data transmission. The light source array A120 may use lasers such as VCSELs as the source of light beams, and may also use other types of light sources such as Micro-LEDs, which emit light beams across a hemisphere rather than a collimated spot by lasers. The light source array A120 may adopt various types of light sources, which may have variances with respect to light emission mode and light spot characteristics. Also, there may be variance with respect to the number of light sources and positions of light sources on the top surface of the VCSEL chip A102, depending on customizable requirements of optical connection. The VCSEL chip A102 and the light source array A120 on top of the VCSEL chip A102 are deployed on the TX side, and are connected via an optical link to the receiving end (RX) side. In this regard, it is hard to predict the specific requirements of the TX side, such as predicting an exact number of light sources of the light source array A120, exact types of light sources, exact positions of light sources on the top surface, as well as light emission mode and light spot characteristics. Therefore, in order to meet all kinds of possible optical connection requirements, a correct fiber bundle optical alignment must be adapted to all possible variances of the requirements of the TX side, so as to establish a reliable optical link between the TX side and the RX side with a good quality of data transmission and a good alignment accuracy.

Still referring to FIG. 1, with the development of data center networks, cloud computing, and large-scale artificial intelligence models, the number of fibers in one fiber bundle, or, the number of cores of a multicore imaging fiber, rapidly increases, and such tendency is further strengthened by an increasing demand for a wide architecture that uses a huge number of channels and corresponding fibers or fiber cores for establishing an optical link, such as a multicore imaging fiber with 1000 cores and 400 channels. As the data scale of data transmission in data center networks rapidly increases, the number of fibers, or the number of cores of a multi-core fiber, also rapidly increases to reach hundreds, or even thousands. And with a huge number of fibers in one fiber bundle or a huge number of cores in a multi-core fiber, the complexity and scale of optical systems for routing light beams and aligning fibers may be greatly increased, and this also increases the costs and size of optical connectors. In this regard, the fiber bundle optical alignment not only has to consider all possible variances of the requirements of the TX side, but also has to consider the complexity and costs associated with the optical connectors in implementations of large data scale. Detailed embodiments with reference to the drawings will be discussed further in details below for describing how the present disclosure provides a solution for the fiber bundle optical alignment, or, a reliable optical link using a multi-core fiber.

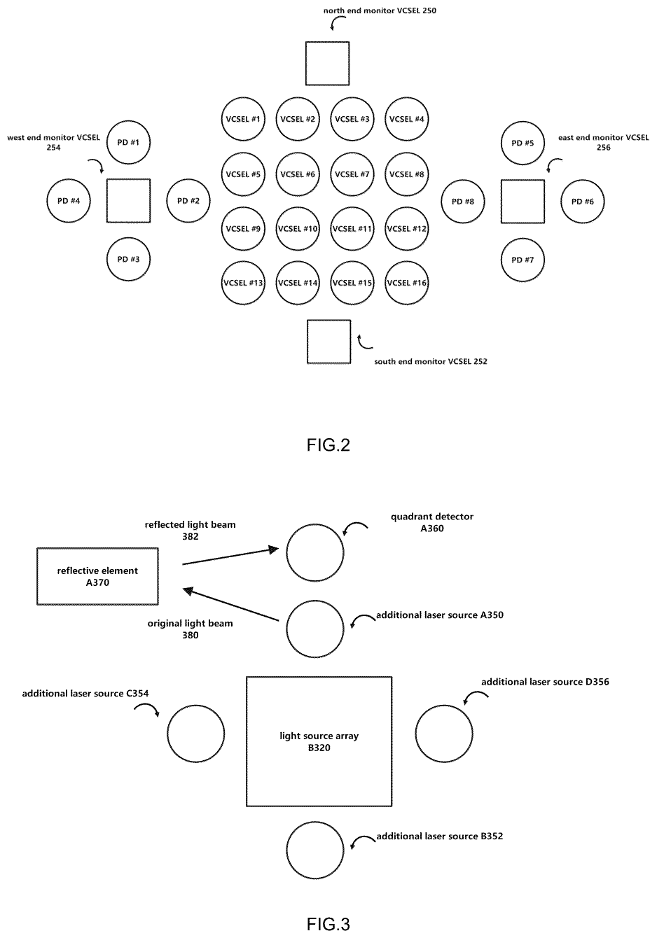

Referring to FIG. 2, FIG. 2 is a schematic diagram illustrating a fiber bundle optical alignment using multiple VCSELs on a chip according to some embodiments. As shown in FIG. 2, a VCSEL array is provided, that includes VCSEL #1 through VCSEL #16. The exact number of the VCSEL array is illustrative only, and a VCSEL chip may have any number of VCSELs that form a VCSEL array. The VCSEL #1 through VCSEL #16 forms a four by four VCSEL array, that has four lines with each line having four VCSELs. The VCSEL array may have any type of distribution of the VCSELs, in other words, the VCSELs on the VCSEL chip may be positioned according to any spatial relationship, such as a matrix of 2 by 8. As mentioned above, there may be variance with respect to the number of light sources and positions of light sources on the top surface of the VCSEL chip, depending on customizable requirements of optical connection. And a correct fiber bundle optical alignment, or, a correct alignment of a multi-core fiber, requires that the VCSELs of the VCSEL array are positioned correctly with respect to the cores of appropriate fibers of a fiber bundle or appropriate fiber cores of a multi-core fiber. For example, VCSEL #2 as shown in FIG. 2 provides a channel for transmitting light, and, VCSEL #15 as shown in FIG. 2 provides another channel for transmitting light. The channel associated with VCSEL #2 and the channel associated with VCSEL #15, in a correct optical alignment, are aligned with corresponding fibers of a fiber bundle respectively, or, are aligned with corresponding cores of a multi-core fiber respectively. Ideally, a light spot generated by the light transmitted by the channel on the end surface of the fiber array, or on a focal plane of the fiber array, is positioned right over the core of the appropriate fiber of a fiber bundle or the appropriate fiber core of a multi-core fiber. However, there are many potential factors that may affect the optical alignment, such as aging effects, temperature fluctuations, mechanical stress, and environment contamination (like corrosion by dust or humidity). When there is an offset of the light spot away from the correct position, such misalignment may cause much of the light transmitted from the channel fails to be coupled into the core of the appropriate fiber of a fiber bundle or the appropriate fiber core of a multi-core fiber, thereby raising failure rates and reducing coupling efficiency.

Still referring to FIG. 2, multiple VCSELs on a chip are used for the fiber bundle optical alignment. Four specific VCSELs, north end monitor VCSEL 250, south end monitor VCSEL 252, west end monitor VCSEL 254, and east end monitor VCSEL 256 are provided. The four monitor VCSELs are surrounded by multiple photodiodes (PD) respectively. As shown in FIG. 2, the west end monitor VCSEL 254 is surrounded by PD #1 through PD #4, and, the east end monitor VCSEL 256 is surrounded by PD #5 through PD #8. While not shown in FIG. 2, the north end monitor VCSEL 250 and the south end monitor VCSEL 252 are also surrounded by multiple PDs respectively. As such, the four PDs that surround one monitor VCSEL, such as PD #1, PD #2, PD #3, and PD #4 that surround the west end monitor VCSEL 254, provide a four-quadrant optical device that includes four quadrant detectors. Each PD (quadrant detector) is configured for sensing at least a portion of a reflected light beam that is originally transmitted by the associated monitor VCSEL, such as PD #1 is configured for sensing at least a portion of a reflected light beam that is originally transmitted by the west end monitor VCSEL 254. In this regard, four PDs that surround a monitor VCSEL define four separate active areas, and therefore, when a reflected light beam hits the center of the monitor VCSEL, the four PDs or the four quadrant detectors may produce an equal electrical output. The four PDs that surround a monitor VCSEL are generally arranged in rectangular coordinates, and the center of the monitor VCSEL is the coordinate origin, such that a light spot over the monitor VCSEL is divided into four spot areas that fall into the four separate active areas respectively. As the four PDs are four identical photoelectric detectors, the electrical output of a given PD is generally defined by the spot area that falls into the active area associated with the given PD. By comparing the electrical outputs from each PD, i.e., each quadrant detector, a central position of the light spot is calculated, and a distance between the central position of the light spot and the coordinate origin which is the center of the monitor VCSEL is calculated. An energy distribution model of the light spot is used to improve the calculation precision, such as using a two-dimensional Gaussian distribution model. Depending on the light emission mode and the light spot characteristics, a two-dimensional Gaussian distribution model or other energy distribution model of the light spot is adopted for establishing a fitting method that determines the central position of the light spot. When the light spot is correctly centered with respect to a monitor VCSEL, the electrical outputs from the four PDs that surround the monitor VCSEL are generally equal. Therefore, if the light spot moves away from the correct position, one or more PDs will receive more or less light and generate a different electrical output consequentially, which indicates the direction and magnitude of the displacement. The centering and misalignment detection are achieved by comparing the electrical outputs from each PD. While FIG. 2 shows that four PDs surround one monitor VCSEL. The number of PDs that surround one monitor VCSEL may be 1, 2, 3, 4 or any suitable value, and may have a variety of arrangements, such as in the shape of a triangle, a rectangle, a pentagon, or a hexagon. Also, the number of PDs that surround one monitor VCSEL may be different from the number of PDs that surround another monitor VCSEL. As shown in FIG. 2, four monitor VCSELs are provided, and each monitor VCSEL with surrounding PDs is used for the centering and misalignment detection of a light spot associated with the monitor VCSEL. For example, the west end monitor VCSEL 254 and the surrounding PDs (PD #1 through PD #4) are used for the centering and misalignment detection of a light spot associated with the west end monitor VCSEL 254, and, the east end monitor VCSEL 256 and the surrounding PDs (PD #5 through PD #8) are used for the centering and misalignment detection of a light spot associated with the east end monitor VCSEL 256. As such, depending on the number of monitor VCSELs provided on chip in addition to the VCSEL array, the number of surrounding PDs associated with each monitor VCSEL might be varied. When only one monitor VCSEL is provided, four surrounding PDs may be deployed to provide an accurate misalignment detection with respect to the single monitor VCSEL. When there are several monitor VCSELs provided, such as three monitor VCSELs or four VCSELs, since the overall fiber bundle optical alignment is based on misalignment detection by all of the monitor VCSELs, the number of surrounding PDs may be set as 3, or 2, or even 1. And different monitor VCSELs may have different number of surrounding PDs, for example, the north end monitor VCSEL 250 may have three rather than four surrounding PDs.

Still referring to FIG. 2, the fiber bundle optical alignment uses one or more monitor VCSELs and associated surrounding PDs for fiber positioning and beam alignment. While more monitor VCSELs and more surrounding PDs help to make sure that light beams are properly aligned and centered, however, this also adds to the costs and complexity of the alignment system. As such, a fine balance may be reached by calibrating the number of monitor VCSELs deployed and the positions of the deployed monitor VCSELs as well as the number and position of surrounding PDs associated with each deployed monitor VCSEL. Because the exact number and position of the VCSELs of the VCSEL array are hard to predict and might change according to customer needs, the deployment of monitor VCSELs and surrounding PDs may be changed so as to be adaptive to all possible variances of the requirements of the TX side. For example, when there are thousands of VCSELs of the VCSEL array, more than four monitor VCSELs may be deployed, such as 12, 24, or 36 monitor VCSELs, which are generally evenly distributed along a circumference of a circle that encloses all of the thousands of VCSELs, by distance or by radius. Because each monitor VCSEL is used to report the misalignment detection based on reflected light beam in local region, this arrangement of monitor VCSELs provides region-sensitive misalignment detection, such that different parts of the VCSEL array composed of a massive number of VCSELs may report their own misalignment detection, which may be then used for determining whether to perform shutting down one part of the VCSEL array while continuing to open another part of the VCSEL array. Meanwhile, since more monitor VCSELs are deployed, the number of surrounding PDs may be set as 3 or 2 or 1, so as to maintain the overall cost and simplify the system. With less surrounding PDs associated with one monitor VCSEL, two or more neighbouring monitor VCSELs may be coordinated to maintain the overall accuracy of misalignment detection.

Referring to FIG. 3, FIG. 3 is a transmitting-end fiber alignment device according to some embodiments. As shown in FIG. 3, the transmitting-end fiber alignment device includes at least one additional laser source that is provided in addition to a light source array B320 including a plurality of light sources. The at least one additional laser source includes additional laser source A350, additional laser source B352, additional laser source C354, and additional laser source D356. The at least one additional laser source is positioned according to a given geometric relationship with respect to a first geometric shape that covers all of the plurality of light sources at a top surface of the light source array B320. The transmitting-end fiber alignment device also includes at least one quadrant detector that corresponds to the at least one additional laser source. For the additional laser source A350, a quadrant detector A360 corresponds to the additional laser source A350. While not shown in FIG. 3, there are at least one quadrant detector that corresponds to each of the additional laser sources. A respective quadrant detector that is each of the at least one quadrant detector, is configured for sensing at least a portion of a reflected light beam that is originally transmitted by a respective additional laser source that corresponds to the respective quadrant detector, such that a misalignment of the light source array is detected. For the additional laser source A350, the quadrant detector A360 is configured for sensing at least a portion of a reflected light beam 382 that is originally transmitted by the additional laser source A350, i.e., a respective additional laser source that corresponds to the respective quadrant detector A360. As such, for each of the additional laser sources, at least one quadrant detector corresponding to the respective additional laser source, is configured for sensing at least a portion of a reflected light beam that is originally transmitted by the respective additional laser source. The centering and misalignment detection achieved by the quadrant detectors such as the quadrant detector A360 is similar to the centering and misalignment detection achieved by the PDs of FIG. 2. Also, the original light beam 380 that is transmitted by the additional laser source A350 is reflected by a reflective element A370, and the reflective light beam 382 is sensed at least partially by the quadrant detector A360. In some embodiments, the reflective element A370 is an optical mirror disposed at the end surface of the fiber bundle or the multi-core fiber. In some embodiments, the reflective element A370 itself is a silicon waveguide fiber or an optic fiber, such that the additional laser source A350 and the corresponding reflective element A370 together establish an additional optical link in addition to the optical links established by the light source array B320 and the fiber array. The additional optical link may be used to measure a change of coupling efficiency for reference.

Still referring to FIG. 3, the transmitting-end fiber alignment device may be used to establish a fiber bundle optical alignment between a fiber array and a light source array B320. And the transmitting-end fiber alignment device must be adapted to all possible variances of the requirements of the TX side, so as to establish a reliable optical link between the TX side and the RX side with a good quality of data transmission and a good alignment accuracy. These possible variances of the requirements on the TX side include an exact number of light sources of the light source array B320, exact types of light sources, exact positions of light sources on the top surface, as well as light emission mode and light spot characteristics. Here, the reflective element A370 is provided on the fiber bundle that includes the fiber array which is supposed to be aligned with the light source array B320. It is noted that data transmission is processed between the light source array B320 and the corresponding fiber array of a fiber bundle, or an array of fiber cores of a multi-core fiber, and therefore, the at least one additional laser source is not involved in the data transmission of the optical link. Rather, as shown in FIG. 3, the original light beam 380 transmitted by the additional laser source A350 is provided in addition to the light beams provided by the light source array B320, and the reflected light beam 382 by the reflective element A370 is also provided independent of the light beams transmitted via the fiber array or fiber cores. In this regard, the additional laser source A350, the reflective element A370, and the quadrant detector A360 together form an optical path for misalignment detection that is independent of the optical paths formed by the light source array B320 and the fiber array. The additional laser source A350 may be a VCSEL such as a monitor VCSEL of FIG. 2, or EEL. The additional laser source A350 and other additional laser sources are capable of emitting a collimated laser spot. The at least one quadrant detector may be a photodetector (PD). As such, the transmitting-end fiber alignment device that includes the at least one additional laser source and the at least one quadrant detector, is adapted to all kinds of possible combination of the light source array B320 and the fiber array of a fiber bundle (alternatively, a set of fiber cores of a multi-core fiber). The light sources of the light source array B320 may be VCSELs or Micro-LEDs, or other types of light sources. The fiber array may include a number of outgoing fibers, fit for the TX side, that are silicon waveguide fibers, a multicore imaging fiber, or active optical cables. Because the transmitting-end fiber alignment device uses the at least one additional laser source and the at least one quadrant detector to establish an independent optical path for misalignment detection, that is separated from and independent of the optical paths between the light source array B320 and the fiber array for data transmission, therefore, the misalignment detection is performable independent of the data transmission. This allows the performing of misalignment detection for a variety of combinations of different types of light source array B320 and different types of fiber array. For example, the light source array B320 may be the 4 by 4 VCSEL array shown in FIG. 2. Further, taking the monitor VCSELs of FIG. 2 for example, the additional laser sources of FIG. 3 may be implemented as monitor VCSELs of FIG. 2, and the quadrant detectors of FIG. 3 may be implemented as PDs of FIG. 2. Just like the deployment of monitor VCSELs and surrounding PDs may be changed so as to be adaptive to all possible variances of the requirements of the TX side, here, the deployment of additional laser sources and corresponding quadrant detectors may be changed so as to be adaptive to all possible variances of the requirements of the TX side. And more detailed embodiments with reference to the drawings are provided below for illustrating the flexibility of configuring the details of the transmitting-end fiber alignment device that includes the at least one additional laser source and the at least one quadrant detector.

Still referring to FIG. 3, at least one additional laser source is positioned according to a given geometric relationship with respect to a first geometric shape that covers all of the plurality of light sources at a top surface of the light source array B320. Here, by introducing the first geometric shape that covers all light sources, and by deploying the additional laser source in addition to the light sources according to a given geometric relationship with respect to the first geometric shape, this helps to simplify the design of the deployment of additional laser sources together with associated quadrant detectors for adapting to all possible variances of the requirements of the TX side, while considering the complexity and costs associated with the optical connectors in implementations of large data scale. As mentioned above, the exact number and position of the light sources and their light emission mode and light spot characteristics may be varied according to customizable needs, such as a 4 by 4 VCSEL array of FIG. 2, or a large number of parallel channels that use Micro-LEDs as transmitters. Variances of the requirements of the TX side indicate that the transmitting-end fiber alignment device is adapted to all kinds of possible combination of the light source array B320 and the fiber array of a fiber bundle (alternatively, a set of fiber cores of a multi-core fiber). The first geometric shape serves to extract useful information about the layout of the light sources of the light source array B320. For example, the first geometric shape may be a rectangular that corresponds to light sources arranged like a matrix. For another example, the first geometric shape may be an enclosing circle that has all light sources located within the circle. After determining the first geometric shape, the given geometric relationship of the additional laser sources with respect to the first geometric shape may be determined, and the internal mathematical details defined by the given geometric relationship may be used to simplify the calculation of the measured light spot against the correct position. Also, since the additional laser sources are positioned according to the given geometric relationship, this arrangement of additional laser sources provides region-sensitive misalignment detection, such that different parts of the light source array B320 may report their own misalignment detection, which may then be used for determining whether to shut down one part while continuing to open another part. As the data scale of data center network rapidly increases, the light source array B320 may include a large number of light sources that transmit light beams through a large number of optic fibers or fiber cores, such as hundreds or thousands of VCSELs. Therefore, a large number of light sources may be distributed over a relatively large area on a top surface of an optical module, such as a VCSEL chip. Due to factors like aging effects, temperature fluctuations, mechanical stress, and environment contamination (like corrosion by dust or humidity), some light sources out of the large number of light sources may be faced with problems of optical alignment and reduced coupling efficiencies. Instead of getting rid of the whole optical module, which may be difficult or impossible to be detached, the particular layout of the additional laser sources that are provided in addition to the light sources, serves to report the misalignment detection in local regions, such that different parts of the light source array B320 that fall into different local regions may report their own misalignment detection respectively. Such region-sensitive misalignment detection is helpful for determining whether to perform shutting down one part of the light source array B320 while continuing to open another part of the light source array B320.

In summary, the transmitting-end fiber alignment device, provides an architecture that includes the at least one additional laser source and the at least one quadrant detector, achieves centering and misalignment detection of each additional laser source based on the sensing of reflected light beam by corresponding quadrant detector; provides reliable optical links and improves alignment accuracy with simplified system design and lower costs; not only considers all possible variances of the requirements of the transmitting end, but also considers the complexity and costs associated with optical connectors in implementations of large data scale; uses the particular layout of the at least one additional laser source to simplify the calculation of the measured light spot as against the correct position, and provide region-sensitive misalignment detection, such that different parts of the light source array may be treated respectively.

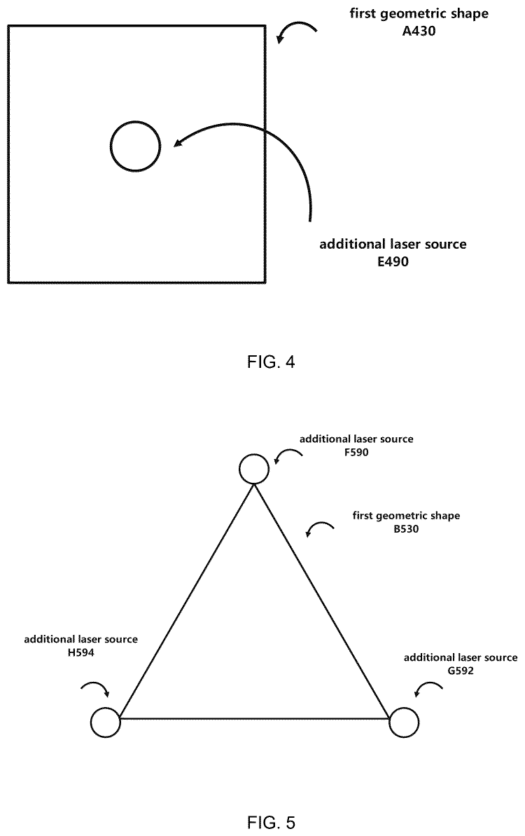

Referring to FIG. 4, FIG. 4 is a schematic diagram illustrating a first setting of additional laser sources according to some embodiments. As mentioned above, the deployment of additional laser sources and corresponding quadrant detectors may be changed so as to be adaptive to all possible variances of the requirements of the TX side. While more additional laser sources and more corresponding quadrant detectors help to make sure that light beams are properly aligned and centered, however, this also adds to the costs and complexity of the alignment system. As such, a fine balance may be reached by calibrating the number of additional laser sources deployed and the positions of the deployed additional laser sources as well as the number and position of corresponding quadrant detectors with respect to each deployed additional laser source. As shown in FIG. 4, the first geometric shape A430 is largely rectangular, and there is only one additional laser source E490 that is positioned at the geometric center of the first geometric shape A430. Since only one additional laser source E490 is provided, four surrounding PDs may be used as corresponding quadrant detectors to provide an accurate misalignment detection with respect to the single additional laser source E490.

Referring to FIG. 5, FIG. 5 is a schematic diagram illustrating a second setting of additional laser sources according to some embodiments. As mentioned above, the deployment of additional laser sources and corresponding quadrant detectors may be changed so as to be adaptive to all possible variances of the requirements of the TX side. While more additional laser sources and more corresponding quadrant detectors help to make sure that light beams are properly aligned and centered, however, this also adds to the costs and complexity of the alignment system. As such, a fine balance may be reached by calibrating the number of additional laser sources deployed and the positions of the deployed additional laser sources as well as the number and position of corresponding quadrant detectors with respect to each deployed additional laser source. As shown in FIG. 5, the first geometric shape B530 is largely triangular, and there are three additional laser sources positioned at three vertices of a triangle, including additional laser source F590, additional laser source G592, and additional laser source H594. Since three additional laser sources are provided, the number of surrounding PDs used as corresponding quadrant detectors may be set as 4, 3, 2, or 1.

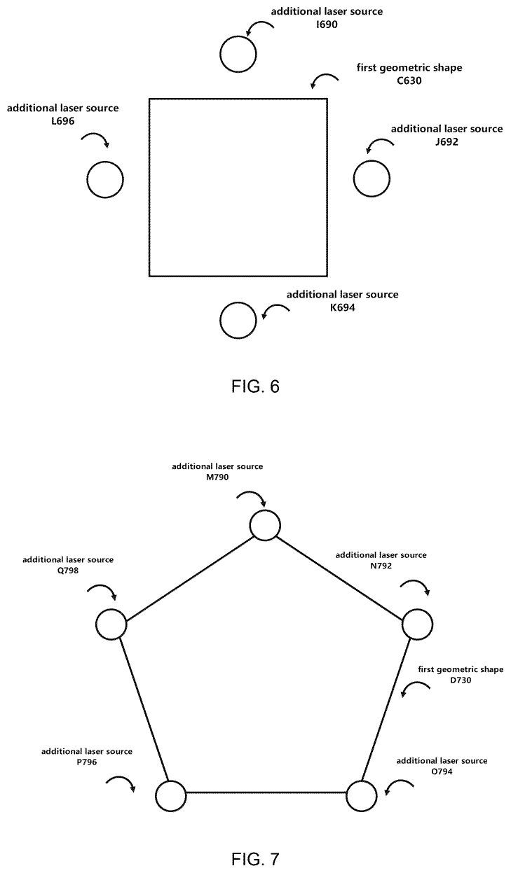

Referring to FIG. 6, FIG. 6 is a schematic diagram illustrating a third setting of additional laser sources according to some embodiments. As mentioned above, the deployment of additional laser sources and corresponding quadrant detectors may be changed so as to be adaptive to all possible variances of the requirements of the TX side. While more additional laser sources and more corresponding quadrant detectors help to make sure that light beams are properly aligned and centered, however, this also adds to the costs and complexity of the alignment system. As such, a fine balance may be reached by calibrating the number of additional laser sources deployed and the positions of the deployed additional laser sources as well as the number and position of corresponding quadrant detectors with respect to each deployed additional laser source. As shown in FIG. 6, the first geometric shape C630 is largely rectangular, and there are four additional laser sources positioned at four dimensions of a rectangle, or at four vertices of a cross, including additional laser source I690, additional laser source J692, additional laser source K694, and additional laser source L696. Since four additional laser sources are provided, the number of surrounding PDs used as corresponding quadrant detectors may be set as 4, 3, 2, or 1.

Referring to FIG. 7, FIG. 7 is a schematic diagram illustrating a fourth setting of additional laser sources according to some embodiments. As mentioned above, the deployment of additional laser sources and corresponding quadrant detectors may be changed so as to be adaptive to all possible variances of the requirements of the TX side. While more additional laser sources and more corresponding quadrant detectors help to make sure that light beams are properly aligned and centered, however, this also adds to the costs and complexity of the alignment system. As such, a fine balance may be reached by calibrating the number of additional laser sources deployed and the positions of the deployed additional laser sources as well as the number and position of corresponding quadrant detectors with respect to each deployed additional laser source. As shown in FIG. 7, the first geometric shape D730 is largely a pentagon, and there are five additional laser sources positioned at five vertices of the pentagon, including additional laser source M790, additional laser source N792, additional laser source O794, additional laser source P796, and additional laser source Q798. Since five additional laser sources are provided, the number of surrounding PDs used as corresponding quadrant detectors may be set as 4, 3, 2, or 1.

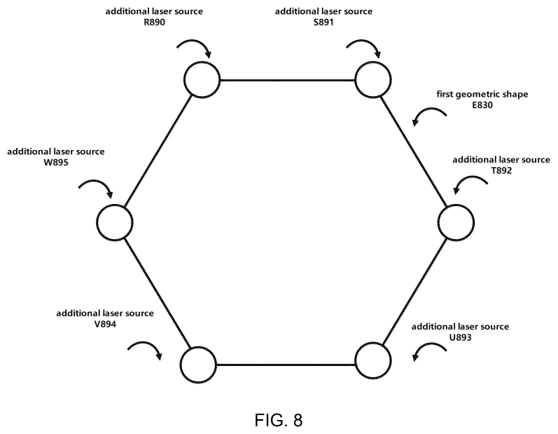

Referring to FIG. 8, FIG. 8 is a schematic diagram illustrating a fifth setting of additional laser sources according to some embodiments. As mentioned above, the deployment of additional laser sources and corresponding quadrant detectors may be changed so as to be adaptive to all possible variances of the requirements of the TX side. While more additional laser sources and more corresponding quadrant detectors help to make sure that light beams are properly aligned and centered, however, this also adds to the costs and complexity of the alignment system. As such, a fine balance may be reached by calibrating the number of additional laser sources deployed and the positions of the deployed additional laser sources as well as the number and position of corresponding quadrant detectors with respect to each deployed additional laser source. As shown in FIG. 8, the first geometric shape E830 is largely a hexagon, and there are six additional laser sources positioned at six vertices of the hexagon, including additional laser source R890, additional laser source S891, additional laser source T892, additional laser source U893, additional laser source V894, and additional laser source W895. Since six additional laser sources are provided, the number of surrounding PDs used as corresponding quadrant detectors may be set as 4, 3, 2, or 1.

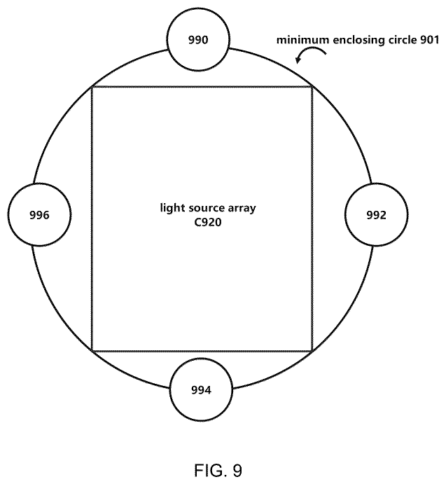

Referring to FIG. 9, FIG. 9 is a schematic diagram illustrating the distribution of additional laser sources along the circumference of the minimum enclosing circle according to some embodiments. As shown in FIG. 9, the area occupied by the light source array C920 is represented by a rectangle. A minimum enclosing circle 901 that encloses the rectangle is shown, and four small circles representing additional laser sources are distributed along the circumference of the minimum enclosing circle 901. As such, the given geometric relationship with respect to the first geometric shape indicates that the at least one additional laser source are positioned on a boundary of the first geometric shape that is a minimum enclosing circle 901, the plurality of light sources are inside the minimum enclosing circle 901. Also, a set-covering algorithm may be used to cover a set of points corresponding to the light sources of the light source array C920. Because the minimum enclosing circle 901 is deployed to make sure that all of the light sources of the light source array C920 are located within the minimum enclosing circle 901, therefore, the four additional laser sources represented by four small circles marked as 990, 992, 994, and 996, which are positioned along the circumference of the minimum enclosing circle 901, meet the requirements of positioning according to a given geometric relationship with respect to the first geometric shape that covers all of the light sources. As such, using the minimum enclosing algorithm or the set-covering algorithm, the minimum enclosing circle 901 may be determined and the positions of four additional laser sources (alternatively, a number of additional laser sources may be deployed) are assigned along the circumference of the minimum enclosing circle 901. This helps to improve the overall accuracy of fiber positioning and misalignment detection.

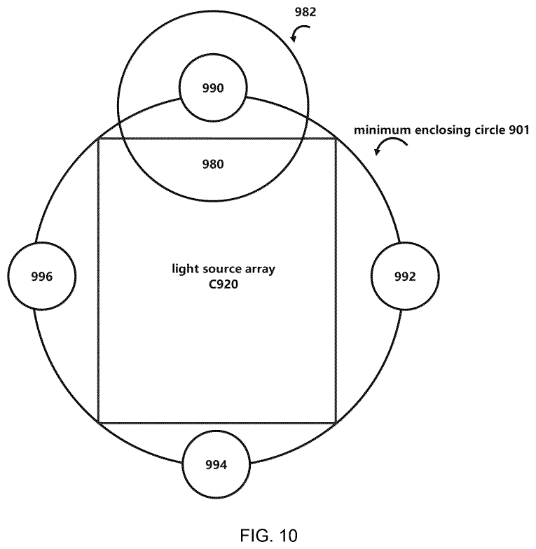

Referring to FIG. 10, FIG. 10 is a schematic diagram illustrating several additional laser sources used for determining regional coupling efficiencies according to some embodiments. FIG. 10 is the same as FIG. 9, except that a medium circle marked as 982 is provided to indicate a local region of the additional laser source marked as 990. As such, the respective additional laser source and the respective reflective element that corresponds to the respective additional laser source are configured for measuring a reference coupling efficiency related to a surrounding region of the respective additional laser source, and, the reference coupling efficiency is used for determining a regional coupling efficiency of one or more light sources out of the plurality of light sources within the surrounding region of the respective additional laser source. As shown in FIG. 10, for the respective additional laser source marked as 990, a surrounding region (marked as 982) of the respective laser source (marked as 990), overlaps with a part of the light source array C920. The overlapping region is marked as 980. As such, light sources out of the light source array C920 that are positioned in the overlapping region marked as 980, correspond to one or more light sources out of the plurality of light sources within the surrounding region (marked as 982) of the respective additional laser source (marked as 990). Accordingly, the architecture that includes the at least one additional laser source and the at least one quadrant detector, provides region-sensitive misalignment detection, such that different parts of the light source array C920 may be treated respectively. For example, the light sources that fall into the overlapping region 980 may be determined to be shut down, if the regional coupling efficiency of these light sources within the surrounding region (marked as 982) that is determined based on the measured reference coupling efficiency, falls below a threshold. As such, instead of getting rid of the whole optical module, which may be difficult or impossible to be detached, the particular layout of the additional laser sources (marked as 990, 992, 994, and 996) that are provided in addition to the light sources, serves to report the misalignment detection in local regions, such that different parts of the light source array C920 that fall into different local regions may report their own misalignment detection respectively. Such region-sensitive misalignment detection is helpful for determining whether to perform shutting down one part of the light source array C920, such as the overlapping region marked as 980, while continuing to open another part of the light source array C920.

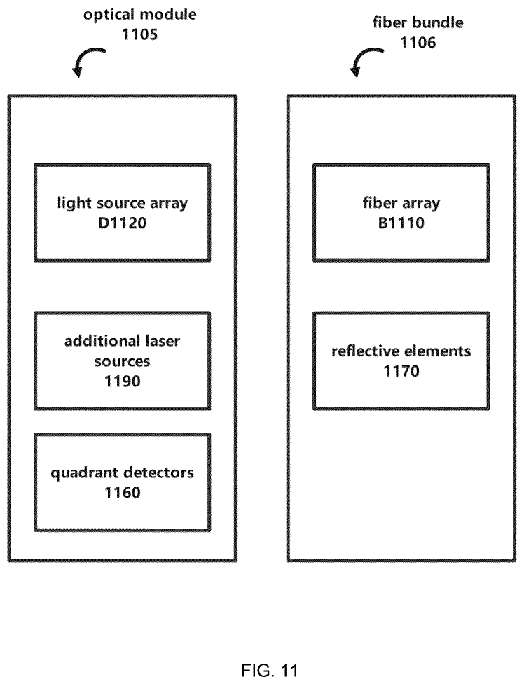

Referring to FIG. 11, FIG. 11 is a schematic diagram illustrating an optical connector according to some embodiments. As shown in FIG. 11, the optical connector provides an optical link between an optical module 1105, like a VCSEL chip, and a fiber bundle 1106. The optical module 1105 includes a light source array D1120, additional laser sources 1190, and quadrant detectors 1160. The fiber bundle 1106 includes a fiber array B1110, and reflective elements 1170. As such, additional laser sources 1190 are provided in addition to light sources of the light source array D1120, and, reflective elements 1170 are provided in addition to the fiber array B1110. It is noted that the fiber array B1110 may be replaced by fiber cores of a multi-core fiber.

Still referring to FIG. 11, the light source array D1120 includes a plurality of light sources. The fiber array B1110 includes a plurality of outgoing fibers. The plurality of light sources are configured for transmitting output light through the plurality of outgoing fibers. The at least one additional laser source (additional laser sources 1190) is provided in addition to the light source array D1120 including the plurality of light sources. The at least one additional laser source (additional laser sources 1190) is positioned according to a given geometric relationship with respect to a first geometric shape that covers all of the plurality of light sources at a top surface of the light source array D1120. The at least one quadrant detector (quadrant detectors 1160) corresponds to the at least one additional laser source (additional laser sources 1190). A respective quadrant detector that is each of the at least one quadrant detector, is configured for sensing at least a portion of a reflected light beam that is originally transmitted by a respective additional laser source that corresponds to the respective quadrant detector, such that a misalignment of the light source array is detected.

In summary, the optical connector, provides an architecture that includes the at least one additional laser source and the at least one quadrant detector, achieves centering and misalignment detection of each additional laser source based on the sensing of reflected light beam by corresponding quadrant detector; provides reliable optical links and improves alignment accuracy with simplified system design and lower costs; not only considers all possible variances of the requirements of the transmitting end, but also considers the complexity and costs associated with optical connectors in implementations of large data scale; uses the particular layout of the at least one additional laser source to simplify the calculation of the measured light spot as against the correct position, and provide region-sensitive misalignment detection, such that different parts of the light source array may be treated respectively.

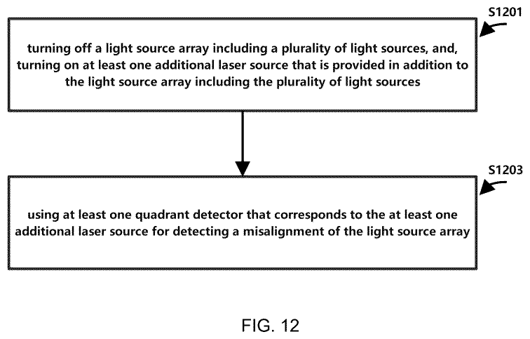

Referring to FIG. 12, FIG. 12 is a flow chart illustrating a method for transmitting-end fiber alignment according to some embodiments. The method includes the following steps.

Step S1201: turning off a light source array including a plurality of light sources, and, turning on at least one additional laser source that is provided in addition to the light source array including the plurality of light sources. Here, at step S1201, the at least one additional laser source is positioned according to a given geometric relationship with respect to a first geometric shape that covers all of the plurality of light sources at a top surface of the light source array.

Step S1203: using at least one quadrant detector that corresponds to the at least one additional laser source for detecting a misalignment of the light source array. Here, at step S1203, a respective quadrant detector that is each of the at least one quadrant detector, is configured for sensing at least a portion of a reflected light beam that is originally transmitted by a respective additional laser source that corresponds to the respective quadrant detector.

In summary, the method for transmitting-end fiber alignment, provides an architecture that includes the at least one additional laser source and the at least one quadrant detector, achieves centering and misalignment detection of each additional laser source based on the sensing of reflected light beam by corresponding quadrant detector; provides reliable optical links and improves alignment accuracy with simplified system design and lower costs; not only considers all possible variances of the requirements of the transmitting end, but also considers the complexity and costs associated with optical connectors in implementations of large data scale; uses the particular layout of the at least one additional laser source to simplify the calculation of the measured light spot as against the correct position, and provide region-sensitive misalignment detection, such that different parts of the light source array may be treated respectively.

Referring to FIG. 1 through FIG. 10, in some embodiments, the plurality of light sources are configured for transmitting output light through a fiber array including a plurality of outgoing fibers. As such, an optical link between the light source array and the fiber array is provided with good alignment accuracy and good link reliability.

In some embodiments, the plurality of outgoing fibers are silicon waveguide fibers, a multicore imaging fiber, or, active optical cables. As such, the transmitting-end fiber alignment device supports various types of outgoing fibers, and is adaptive to various transmission requirements at TX side.

In some instances, the plurality of outgoing fibers are mapped to the plurality of light sources in a one-to-one correspondence. Light sources may be VCSELs that emit a collimated light, and the mapping between outgoing fibers and light sources may be a one-to-one correspondence. As such, it is helpful to maximize the usage of fiber resources.

In some instances, the plurality of outgoing fibers are mapped to the plurality of light sources in a multiple-to-one correspondence. Light sources may be Mirco-LEDs that emit light beams across a hemisphere. Therefore, by using fiber resources in spare, one light source, i.e., one channel, may be mapped to more than one outgoing fibers. As such, a single Micro-LDE is mapped onto multiple outgoing fibers, or multiple fiber cores of a multi-core fiber, and such approach further relaxes alignment accuracy requirements, further reducing the costs and complexity of the optical link.

In some embodiments, at least one reflective element is provided in addition to the fiber array and positioned according to the given geometric relationship with respect to a second geometric shape that covers all of the plurality of outgoing fibers at an end surface of the fiber array. The at least one reflective element is mapped to the at least one additional laser source in a one-to-one correspondence, and, the respective quadrant detector is configured for sensing at least a portion of the reflected light beam that is originally transmitted by the respective additional laser source that corresponds to the respective quadrant detector and reflected by a respective reflective element out of the at least one reflective element that corresponds to the respective additional laser source. As such, at least one reflective element is provided in addition to the fiber array. The additional laser source, the reflective element, and the quadrant detector together form an optical path for misalignment detection that is independent of the optical paths formed by the light source array and the fiber array.

In some instances, a size of the first geometric shape that covers all of the plurality of light sources at the top surface of the light source array is substantially the same as a size of the second geometric shape that covers all of the plurality of outgoing fibers at the end surface of the fiber array. As such, the alignment accuracy is improved.

In some instances, the at least one reflective element is an optical mirror made of free-space MEMS. As such, an optical mirror is provided to reflect the light beams originally transmitted by the additional laser sources. At least one quadrant detector is used to sense the reflected light beams by the at least one reflective element, such that the position of the light spot by the reflected light beam may be calculated for misalignment detection.

In some instances, the at least one reflective element is a silicon waveguide fiber, or, an optical fiber. The reflective element itself is a silicon waveguide fiber or an optic fiber, such that the additional laser source and the corresponding reflective element together establish an additional optical link in addition to the optical links established by the light source array and the fiber array. As such, the additional optical link may be used to measure a change of coupling efficiency for reference.

In some embodiments, the respective additional laser source and the respective reflective element that corresponds to the respective additional laser source are configured for measuring a reference coupling efficiency related to a surrounding region of the respective additional laser source, and, the reference coupling efficiency is used for determining a regional coupling efficiency of one or more light sources out of the plurality of light sources within the surrounding region of the respective additional laser source. As such, since the additional laser sources are positioned according to the given geometric relationship, this arrangement of additional laser sources provides region-sensitive misalignment detection, such that different parts of the light source array may report their own misalignment detection, which may then be used for determining whether to shut down one part while continuing to open another part. As the data scale of data center network rapidly increases, the light source array may include a large number of light sources that transmit light beams through a large number of optic fibers or fiber cores, such as hundreds or thousands of VCSELs. Therefore, a large number of light sources may be distributed over a relatively large area on a top surface of an optical module, such as a VCSEL chip. Due to factors like aging effects, temperature fluctuations, mechanical stress, and environment contamination (like corrosion by dust or humidity), some light sources out of the large number of light sources may be faced with problems of optical alignment and reduced coupling efficiencies. Instead of getting rid of the whole optical module, which may be difficult or impossible to be detached, the particular layout of the additional laser sources that are provided in addition to the light sources, serves to report the misalignment detection in local regions, such that different parts of the light source array that fall into different local regions may report their own misalignment detection respectively. Such region-sensitive misalignment detection is helpful for determining whether to perform shutting down one part of the light source array while continuing to open another part of the light source array.

In some instances, the regional coupling efficiency is used for a decision of shutting down the one or more light sources out of the plurality of light sources within the surrounding region of the respective additional laser source, and, the measuring the reference coupling efficiency is performed independent of data transmission by the light source array in different time divisions. As such, the respective additional laser source and the respective reflective element that corresponds to the respective additional laser source are configured for measuring a reference coupling efficiency related to a surrounding region of the respective additional laser source, and, the reference coupling efficiency is used for determining a regional coupling efficiency of one or more light sources out of the plurality of light sources within the surrounding region of the respective additional laser source. The centering and misalignment detection as well as the measuring the reference coupling efficiency, are performed through additional laser sources that are provided in addition to the light sources of the light source array. Accordingly, the architecture that includes the at least one additional laser source and the at least one quadrant detector, provides region-sensitive misalignment detection, such that different parts of the light source array may be treated respectively. Instead of getting rid of the whole optical module, which may be difficult or impossible to be detached, the particular layout of the additional laser sources that are provided in addition to the light sources, serves to report the misalignment detection in local regions, such that different parts of the light source array that fall into different local regions may report their own misalignment detection respectively. Such region-sensitive misalignment detection is helpful for determining whether to perform shutting down one part of the light source array, while continuing to open another part of the light source array.

In some embodiments, a total number of the at least one additional laser source is one, and, the given geometric relationship with respect to the first geometric shape indicates that the at least one additional laser source is positioned at a geometric center of the first geometric shape. As such, referring to FIG. 4, the first geometric shape is largely rectangular, and there is only one additional laser source that is positioned at the geometric center of the first geometric shape. The deployment of additional laser sources and corresponding quadrant detectors may be changed so as to be adaptive to all possible variances of the requirements of the TX side. While more additional laser sources and more corresponding quadrant detectors help to make sure that light beams are properly aligned and centered, however, this also adds to the costs and complexity of the alignment system. As such, a fine balance may be reached by calibrating the number of additional laser sources deployed and the positions of the deployed additional laser sources as well as the number and position of corresponding quadrant detectors with respect to each deployed additional laser source.

In some embodiments, a total number of the at least one additional laser source is three, and, the given geometric relationship with respect to the first geometric shape indicates that the at least one additional laser source are positioned at three vertices of a triangle respectively, or, the total number of the at least one additional laser source is four, and, the given geometric relationship with respect to the first geometric shape indicates that the at least one additional laser source are positioned at four vertices of a cross respectively, or, the total number of the at least one additional laser source is five, and, the given geometric relationship with respect to the first geometric shape indicates that the at least one additional laser source are positioned at five vertices of a pentagon respectively, or, the total number of the at least one additional laser source is six, and, the given geometric relationship with respect to the first geometric shape indicates that the at least one additional laser source are positioned at six vertices of a hexagon respectively. As such, several examples are provided for illustrating the flexibility of configuring the details of the transmitting-end fiber alignment device that includes the at least one additional laser source and the at least one quadrant detector. Referring to FIG. 5, the first geometric shape B530 is largely triangular, and there are three additional laser sources positioned at three vertices of a triangle. Referring to FIG. 6, the first geometric shape C630 is largely rectangular, and there are four additional laser sources positioned at four dimensions of a rectangle, or at four vertices of a cross. Referring to FIG. 7, the first geometric shape D730 is largely a pentagon, and there are five additional laser sources positioned at five vertices of the pentagon. Referring to FIG. 7, the first geometric shape D730 is largely a pentagon, and there are five additional laser sources positioned at five vertices of the pentagon. Referring to FIG. 8, the first geometric shape E830 is largely a hexagon, and there are six additional laser sources positioned at six vertices of the hexagon.

In some embodiments, a total number of the at least one additional laser source is at least three, and, the given geometric relationship with respect to the first geometric shape indicates that the at least one additional laser source are positioned along a circumference of the first geometric shape that is determined based on a set-covering algorithm for covering a set of points corresponding to the plurality of light sources. As such, a set-covering algorithm may be used to cover a set of points corresponding to the light sources of the light source array.

In some embodiments, a total number of the at least one additional laser source is at least three, and, the given geometric relationship with respect to the first geometric shape indicates that the at least one additional laser source are positioned on a boundary of the first geometric shape that is a minimum enclosing circle, the plurality of light sources are inside the minimum enclosing circle. As such, using the minimum enclosing algorithm or the set-covering algorithm, the minimum enclosing circle may be determined and the positions of additional laser sources are assigned along the circumference of the minimum enclosing circle. This helps to improve the overall accuracy of fiber positioning and misalignment detection.

In some instances, the given geometric relationship with respect to the first geometric shape further indicates that, the at least one additional laser source are evenly distributed along a circumference of the minimum enclosing circle, or, the at least one additional laser source are distributed in a centrally symmetric manner around a center of the minimum enclosing circle. As such, the alignment precision is improved.

In some instances, the given geometric relationship with respect to the first geometric shape further indicates that the at least one additional laser source are distributed at every preset angle along a center of the minimum enclosing circle, and, the preset angle is 30 degrees, 45 degrees, 60 degrees, 72 degrees, 90 degrees, or 120 degrees. As such, the architecture that includes the at least one additional laser source and the at least one quadrant detector, provides region-sensitive misalignment detection, such that different parts of the light source array may be treated respectively. As such, instead of getting rid of the whole optical module, which may be difficult or impossible to be detached, the particular layout of the additional laser sources that are provided in addition to the light sources, serves to report the misalignment detection in local regions, such that different parts of the light source array that fall into different local regions may report their own misalignment detection respectively. Such region-sensitive misalignment detection is helpful for determining whether to perform shutting down one part of the light source array, while continuing to open another part of the light source array.

In some embodiments, the at least one additional laser source is one or more VCSELs, and, the plurality of light sources are VCSELs or Micro-LEDs. As such, the transmitting-end fiber alignment device is adapted to all kinds of possible combination of the light source array and the fiber array of a fiber bundle (alternatively, a set of fiber cores of a multi-core fiber).

To the extent that the term “includes” or “including” is employed in the detailed description or the claims, it is intended to be inclusive in a manner similar to the term “comprising” as that term is interpreted when employed as a transitional word in a claim. Furthermore, to the extent that the term “or” is employed in the detailed description or claims (e.g., A or B) it is intended to mean “A or B or both.” When the applicants intend to indicate “only A or B but not both”, then the term “only A or B but not both” will be employed. Thus, use of the term “or” herein is the inclusive, and not the exclusive use. See, Bryan A. Garner, A Dictionary of Modern Legal Usage 624 (2d. Ed. 1995).

While example systems, methods, and so on, have been illustrated by describing examples, and while the examples have been described in considerable detail, it is not the intention of the applicants to restrict or in any way limit scope to such detail. It is, of course, not possible to describe every conceivable combination of components or methodologies for purposes of describing the systems, methods, and so on, described herein. Additional advantages and modifications will readily appear to those skilled in the art. Therefore, the invention is not limited to the specific details, the representative apparatus, and illustrative examples shown and described. Thus, this application is intended to embrace alterations, modifications, and variations that fall within the scope of the appended claims. Furthermore, the preceding description is not meant to limit the scope of the invention. Rather, the scope of the invention is to be determined by the appended claims and their equivalents.

The detailed embodiments provided in the present disclosure can be implemented by any one or a combination of hardware, software, firmware, or solid-state logic circuits, and can be implemented in combination with signal processing, control, and/or dedicated circuits. The equipment(s) or device(s) provided in the detailed embodiments of the present disclosure may include one or more processors (a microprocessor, a controller, a digital signal processor (DSP), an application specific integrated circuit (ASIC), a field programmable gate array(FPGA) and so on), and these processors process various computer-executable instructions to control the operations of the equipment(s) or device(s). The equipment(s) or device(s) provided in the detailed embodiments of the present disclosure may include a system bus or a data transmission system that couples various components together. The system bus may include any one of different bus structures or a combination of different bus structures, such as a memory bus or a memory controller, a peripheral bus, a universal serial bus, and/or a process or a local bus using any of a variety of bus architectures. The equipment(s) or device(s) provided in the detailed embodiments of the present disclosure may be provided separately, may also be a part of the system, or may be a part of other equipment or devices.

The detailed embodiments provided by the present disclosure may include a computer-readable storage medium or a combination with a computer-readable storage medium, such as one or more storage devices capable of providing non-transitory data storage. The computer-readable storage medium/storage device may be configured to store data, programmers and/or instructions, which when executed by the processor of the equipment(s) or device(s) provided in the present disclosure, would allow the equipment(s) or device(s) to implement related operations. The computer-readable storage medium/storage device may include one or more of the following characteristics: volatile, nonvolatile, dynamic, static, read/write, read-only, random access, sequential access, location addressability, file addressability and content addressability. In one or more exemplary embodiments, the computer-readable storage medium/storage device may be integrated into the equipment(s) or device(s) provided in the detailed embodiments of the present disclosure or belong to a public system. The computer-readable storage media/storage devices can include optical storage devices, semiconductor storage devices and/or magnetic storage devices, etc., and can also include random access memory (RAM), flash memory, read-only memory (ROM), erasable and programmable read-only memory (EPROM), electrically erasable programmable read-only memory (EEPROM), registers, hard disk, removable disk, recordable and/or rewritable compact disc (CD), digital versatile disc (DVD), large capacity storage medium device or any other form of suitable storage medium.

It will be appreciated that various of the above-disclosed embodiments and other features and functions, or alternatives or varieties thereof, may be desirably combined into many other different systems or applications. Also that various presently unforeseen or unanticipated alternatives, modifications, variations or improvements therein may be subsequently made by those skilled in the art which are also intended to be encompassed by the following claims.

What is claimed is:

1. A transmitting-end fiber alignment device, comprising:
at least one additional laser source that is provided in addition to a light source array including a plurality of light sources, wherein the at least one additional laser source is positioned according to a given geometric relationship with respect to a first geometric shape that covers all of the plurality of light sources at a top surface of the light source array; and
at least one quadrant detector that corresponds to the at least one additional laser source, wherein, a respective quadrant detector that is each of the at least one quadrant detector, is configured for sensing at least a portion of a reflected light beam that is originally transmitted by a respective additional laser source that corresponds to the respective quadrant detector, such that a misalignment of the light source array is detected.

2. The transmitting-end fiber alignment device according to claim 1, wherein the plurality of light sources are configured for transmitting output light through a fiber array including a plurality of outgoing fibers.

3. The transmitting-end fiber alignment device according to claim 1, wherein the plurality of outgoing fibers are silicon waveguide fibers, a multicore imaging fiber, or, active optical cables.

4. The transmitting-end fiber alignment device according to claim 2, wherein the plurality of outgoing fibers are mapped to the plurality of light sources in a one-to-one correspondence.

5. The transmitting-end fiber alignment device according to claim 2, wherein the plurality of outgoing fibers are mapped to the plurality of light sources in a multiple-to-one correspondence.

6. The transmitting-end fiber alignment device according to claim 2, wherein at least one reflective element is provided in addition to the fiber array and positioned according to the given geometric relationship with respect to a second geometric shape that covers all of the plurality of outgoing fibers at an end surface of the fiber array, the at least one reflective element is mapped to the at least one additional laser source in a one-to-one correspondence, and, the respective quadrant detector is configured for sensing at least a portion of the reflected light beam that is originally transmitted by the respective additional laser source that corresponds to the respective quadrant detector and reflected by a respective reflective element out of the at least one reflective element that corresponds to the respective additional laser source.

7. The transmitting-end fiber alignment device according to claim 6, wherein a size of the first geometric shape that covers all of the plurality of light sources at the top surface of the light source array is substantially the same as a size of the second geometric shape that covers all of the plurality of outgoing fibers at the end surface of the fiber array.

8. The transmitting-end fiber alignment device according to claim 6, wherein the at least one reflective element is an optical mirror made of free-space MEMS.

9. The transmitting-end fiber alignment device according to claim 6, wherein the at least one reflective element is a silicon waveguide fiber, or, an optical fiber.

10. The transmitting-end fiber alignment device according to claim 9, wherein the respective additional laser source and the respective reflective element that corresponds to the respective additional laser source are configured for measuring a reference coupling efficiency related to a surrounding region of the respective additional laser source, and, the reference coupling efficiency is used for determining a regional coupling efficiency of one or more light sources out of the plurality of light sources within the surrounding region of the respective additional laser source.

11. The transmitting-end fiber alignment device according to claim 10, wherein the regional coupling efficiency is used for a decision of shutting down the one or more light sources out of the plurality of light sources within the surrounding region of the respective additional laser source, and, the measuring the reference coupling efficiency is performed independent of data transmission by the light source array in different time divisions.

12. The transmitting-end fiber alignment device according to claim 1, wherein a total number of the at least one additional laser source is one, and, the given geometric relationship with respect to the first geometric shape indicates that the at least one additional laser source is positioned at a geometric center of the first geometric shape.

13. The transmitting-end fiber alignment device according to claim 1, wherein, a total number of the at least one additional laser source is three, and, the given geometric relationship with respect to the first geometric shape indicates that the at least one additional laser source are positioned at three vertices of a triangle respectively, or,
the total number of the at least one additional laser source is four, and, the given geometric relationship with respect to the first geometric shape indicates that the at least one additional laser source are positioned at four vertices of a cross respectively, or,
the total number of the at least one additional laser source is five, and, the given geometric relationship with respect to the first geometric shape indicates that the at least one additional laser source are positioned at five vertices of a pentagon respectively, or,
the total number of the at least one additional laser source is six, and, the given geometric relationship with respect to the first geometric shape indicates that the at least one additional laser source are positioned at six vertices of a hexagon respectively.

14. The transmitting-end fiber alignment device according to claim 1, wherein a total number of the at least one additional laser source is at least three, and, the given geometric relationship with respect to the first geometric shape indicates that the at least one additional laser source are positioned along a circumference of the first geometric shape that is determined based on a set-covering algorithm for covering a set of points corresponding to the plurality of light sources.

15. The transmitting-end fiber alignment device according to claim 1, wherein a total number of the at least one additional laser source is at least three, and, the given geometric relationship with respect to the first geometric shape indicates that the at least one additional laser source are positioned on a boundary of the first geometric shape that is a minimum enclosing circle, the plurality of light sources are inside the minimum enclosing circle.

16. The transmitting-end fiber alignment device according to claim 15, wherein the given geometric relationship with respect to the first geometric shape further indicates that, the at least one additional laser source are evenly distributed along a circumference of the minimum enclosing circle, or, the at least one additional laser source are distributed in a centrally symmetric manner around a center of the minimum enclosing circle.

17. The transmitting-end fiber alignment device according to claim 15, wherein the given geometric relationship with respect to the first geometric shape further indicates that the at least one additional laser source are distributed at every preset angle along a center of the minimum enclosing circle, and, the preset angle is 30 degrees, 45 degrees, 60 degrees, 72 degrees, 90 degrees, or 120 degrees.

18. The transmitting-end fiber alignment device according to claim 1, the at least one additional laser source is one or more VCSELs, and, the plurality of light sources are VCSELs or Micro-LEDs.

19. An optical connector, comprising:
a light source array including a plurality of light sources;
a fiber array including a plurality of outgoing fibers, wherein the plurality of light sources are configured for transmitting output light through the plurality of outgoing fibers;
at least one additional laser source that is provided in addition to the light source array including the plurality of light sources, wherein the at least one additional laser source is positioned according to a given geometric relationship with respect to a first geometric shape that covers all of the plurality of light sources at a top surface of the light source array; and
at least one quadrant detector that corresponds to the at least one additional laser source, wherein, a respective quadrant detector that is each of the at least one quadrant detector, is configured for sensing at least a portion of a reflected light beam that is originally transmitted by a respective additional laser source that corresponds to the respective quadrant detector, such that a misalignment of the light source array is detected.

20. A method for transmitting-end fiber alignment, comprising:
turning off a light source array including a plurality of light sources, and, turning on at least one additional laser source that is provided in addition to the light source array including the plurality of light sources, wherein the at least one additional laser source is positioned according to a given geometric relationship with respect to a first geometric shape that covers all of the plurality of light sources at a top surface of the light source array; and
using at least one quadrant detector that corresponds to the at least one additional laser source for detecting a misalignment of the light source array, wherein, a respective quadrant detector that is each of the at least one quadrant detector, is configured for sensing at least a portion of a reflected light beam that is originally transmitted by a respective additional laser source that corresponds to the respective quadrant detector.
